(19) United States
(12) Patent Application Publication
(10) Pub. No.: US 2026/0276217 A1
(43) Pub. Date: Sep. 17, 2026

(54) INDOOR UNIT OF FAN WALL TYPE AIR CONDITIONER, AND FAN WALL TYPE AIR CONDITIONER

(71) Applicant: GUANGDONG ENVICOOL TECHNOLOGY CO., LTD., Zhongshan City (CN)

(72) Inventors: HONGHAO ZHENG, Zhongshan City (CN); XURONG CHEN, Zhongshan City (CN); PENG ZHAO, Zhongshan City (CN); YE WU, Zhongshan City (CN)

(73) Assignee: GUANGDONG ENVICOOL TECHNOLOGY CO., LTD., Zhongshan City (CN)

(21) Appl. No.: 19/668,794

(22) Filed: May 5, 2026

Related U.S. Application Data
(63) Continuation of application No. PCT/CN2025/138599, filed on Nov. 28, 2025.

(30) Foreign Application Priority Data
Dec. 16, 2024 (CN) 202411854331.1

(51) Int. Cl. F24F 1/0003; H05K 7/20; F24F 1/0073

(52) U.S. Cl. CPC F24F 1/0003; H05K 7/20827; F24F 1/0073; F24F 2221/36

(57) ABSTRACT

An indoor unit of a fan wall type air conditioner includes a first fan wall module which includes multiple first cold air chambers arranged side by side. A first fan assembly is arranged in each of the first cold air chambers. An upper portion of a middle one of the first cold air chambers is covered with a door in which a display module is inlaid. A low-voltage electric control box and a high-voltage electric control box are sequentially arranged, from outside to inside, in the middle first cold air chamber and covered by the door. Low-voltage components are arranged in the low-voltage electric control box, and high-voltage components are arranged in the high-voltage electric control box. In the indoor unit of the fan wall type air conditioner, arrangement of the internal components is optimized, the air outlet effect is effectively improved, and operation and maintenance are facilitated for users.

### CROSS REFERENCE TO RELATED APPLICATIONS

The present application is a continuation application of the international patent application No. PCT/CN2025/138599 filed on Nov. 28, 2025, which claims priority of the Chinese patent application No. CN202411854331.1 filed on Dec. 16, 2024. Contents of the related applications are incorporated herein by its entireties.

### FIELD

The present application relates to the technical field of temperature control equipment, in particular to an indoor unit of a fan wall type air conditioner, and a fan wall type air conditioner.

### BACKGROUND

At present, in the construction of some large-scale data centres, fan wall type chilled-water computer room air conditioners are generally adopted to improve the efficiency of fans and overall energy efficiency. Such products have the advantages of high air output and low resistance and achieves a greater air output, a higher refrigerating capacity and lower power consumption; meanwhile, the modular design of the unit allows for field assembly by users and realizes a higher refrigerating capacity and a greater air output, thus satisfying environmental requirements of large-scale data centres.

In the implementation process of the application, the inventor found that the prior art has at least the following problems: modular fan wall type devices are inconvenient to install, the layout inside the fan wall modules is unreasonable, operation and maintenance are inconvenient, and the disordered layout compromises the air outlet effect of the fan wall type devices.

### SUMMARY

In view of this, the application provides an indoor unit of a fan wall type air conditioner, and a fan wall type air conditioner to solve the problem of unreasonable layout in the prior art, improve the air outlet effect of fan wall type devices, and facilitate operation and maintenance for users.

To fulfil the above purpose, the technical solution of the embodiments of the application is implemented as follows:

In one aspect, the present application provides an indoor unit of a fan wall type air conditioner, comprising a first fan wall module. The first fan wall module comprises multiple first cold air chambers which are arranged in a row, and a first fan assembly is arranged in each of the first cold air chambers. An upper portion of a middle one of the first cold air chambers is covered with a door, a display module is inlaid in the door, a low-voltage electric control box and a high-voltage electric control box are sequentially arranged, from outside to inside, in the middle one of the first cold air chambers located on an inner side of the door, low-voltage components are arranged in the low-voltage electric control box, and high-voltage components are arranged in the high-voltage electric control box.

In an optional embodiment, the low-voltage electric control box is hinged to wall surfaces of the middle one of the first cold air chambers and is able to rotate with respect to the wall surfaces of the middle one of the first cold air chambers to expose the high-voltage electric control box.

In an optional embodiment, a plurality of heat-dissipation holes is formed in a shell of the low-voltage electric control box and/or the high-voltage electric control box.

In an optional embodiment, the first fan assembly comprises a first fan and a first fan support, the first fan is fixed to the first fan support, and the first fan support is fixedly connected to wall surfaces of a corresponding one of the first cold air chambers in which the first fan assembly is received.

In an optional embodiment, the first fan support is detachably connected to the wall surfaces of the corresponding first cold air chamber.

In an optional embodiment, an active power filter (APF) and a reactor are arranged in the first fan wall module.

In an optional embodiment, the APF and the reactor are arranged at a bottom of the first fan wall module and each of the APF and the reactor is located at a junction of adjacent two said first cold air chambers.

In an optional embodiment, an APF radiator is arranged on the APF, and an air outlet direction of a fan of the APF radiator is consistent with that of the first fan assembly.

In an optional embodiment, the indoor unit further comprises a second fan wall module which comprises multiple second cold air chambers arranged side by side. A second fan assembly is arranged in each of the second cold air chambers; the second fan wall module is arranged above the first fan wall module, and air inlet and out directions of the second fan wall module are consistent with those of the first fan wall module respectively.

In an optional embodiment, the second fan assembly is the same as the first fan assembly in structure.

In an optional embodiment, position limiters are arranged at four corners of a top of the first fan wall module respectively, each of the position limiters comprises a fixing portion and a positioning portion, the fixing portion is fixedly connected to outer walls of the first fan wall module, and the positioning portion is arranged at a top of the fixing portion and bent outwards and inclinedly from the fixing portion to form a guide and limit structure which is configured to facilitate installation and positioning of the second fan wall module on the first fan wall module.

In an optional embodiment, a detachable first maintenance plate is arranged at a top of the first fan wall module, and a first pipe assembly is arranged in the chambers below the first maintenance plate;

a detachable second maintenance plate is arranged at a bottom of the second fan wall module and corresponds to the first maintenance plate, and a second pipe assembly is arranged in the chambers above the second maintenance plate;

the first maintenance plate and the second maintenance plate are configured to enlarge an operation space.

In an optional embodiment, by further comprising a connecting hose assembly, wherein the connecting hose assembly comprises a corrugated hose and two loose flanges disposed around the corrugated hose, and the two loose flanges are respectively connected to the first pipe assembly and the second pipe assembly.

In an optional embodiment, the indoor unit further comprises a valve assembly, wherein the valve assembly is arranged in the first fan wall module and is close to side plates on two sides of the first fan wall module, and the side plates are detachably connected to walls of the corresponding first cold air chambers.

In an optional embodiment, the indoor unit further comprises a sealing member, wherein the sealing member is arranged between the first fan wall module and the second fan wall module.

In an optional embodiment, frames and panels of the first fan wall module and the second fan wall module are made from galvanized plates coated with a protective material, and fasteners between the panels and the frames are made from stainless steel.

In an optional embodiment, lifting holes and forklift holes are formed in a bottom of the first fan wall module and a bottom of the second fan wall module respectively.

In an optional embodiment, levelling foundation bolts are arranged at a bottom of the first fan wall module.

In an optional embodiment, the first fan wall module and the second fan wall module each further comprise a filter screen, a return air valve, a heat exchanger and an air outlet louver which are sequentially arranged from an air inlet side thereof to an air outlet side thereof.

In another aspect, the present application provides a fan wall type air conditioner comprising an outdoor unit and the indoor unit disclosed above. The outdoor unit and the indoor unit are connected electrically and in fluid communication with each other by means of a pipeline to form a refrigerant circulation system.

The application has at least the following beneficial effects: according to the indoor unit of a fan wall type air conditioner provided by the invention, the display module is arranged on the door, and the door is arranged on the upper portion of the corresponding first cold air chamber, such that users may easily watch and operate the display module and may easily open the door to maintain components inside. The low-voltage electric control box and the high-voltage electric control box are arranged from outside to inside in an overlapped manner, such that the obstruction of an air outlet surface of the corresponding first cold air chamber is reduced, thus improving the air outlet effect of fan wall type devices. The fan wall type air conditioner provided by the application includes the indoor unit of a fan wall type air conditioner, thus having the same beneficial effects as the indoor unit of a fan wall type air conditioner.

### BRIEF DESCRIPTION OF THE DRAWINGS

FIG. 1 is a schematic diagram of an internal structure of an indoor unit of a fan wall type air conditioner in accordance with an embodiment of the application, viewed from an air outlet side with an air outlet louver being removed.

FIG. 2 is a schematic front view of the indoor unit of a fan wall type air conditioner according to the embodiment of the application (air outlet side).

FIG. 3 is a schematic side view of a low-voltage electric control box and a high-voltage electric control box according to an embodiment of the application.

FIG. 3A is a schematic side view of the indoor unit of a fan wall type air conditioner, illustrating a first fan assembly and a reactor thereof.

FIG. 4 is a schematic diagram of a first fan wall module and a second fan wall module in an installation state according to one embodiment of the application.

FIG. 5 is an enlarged view of part A in FIG. 4.

FIG. 6 is a schematic side view of the internal structure of the indoor unit of a fan wall type air conditioner according to the embodiment of the application.

FIG. 6A is a schematic side view of the indoor unit of a fan wall type air conditioner according to an embodiment of the application.

FIG. 7 is a schematic diagram of the internal structure of the indoor unit of a fan wall type air conditioner according to the embodiment of the application, viewed from another perspective (air inlet side, without a filter screen).

FIG. 8 is a schematic diagram of the indoor unit of a fan wall type air conditioner in an application state according to an embodiment of the application, the arrows indicating an air circulation direction.

### REFERENCE SIGNS

1, first fan wall module; 11, first cold air chamber; 12, first fan assembly; 121, first fan; 122, first fan support; 13, low-voltage electric control box; 14, active power filter; 142, APF radiator; 144, fan; 15, reactor; 16, levelling foundation bolt; 17, forklift hole; 18, position limiter; 181, fixing portion; 182, positioning portion; 19, door; 191, display module; 110, high-voltage electric control box; 111, first pipe assembly; 112, valve assembly; 113, side plate; 114, lifting hole; 2, second fan wall module; 21, second cold air chamber; 22, second fan assembly; 23, second pipe assembly; 210, first maintenance plate; 220, second maintenance plate; 230, sealing member 230; 3, connecting hose assembly; 4, heat exchanger; 5, filter screen; 6, air outlet louver; 7, return air valve; 8, sealed heat passage; 9, wall; 10, indoor air outlet passage.

### DESCRIPTION OF THE EMBODIMENTS

The technical solution of the application is described in further detail below with reference to the accompanying drawings and specific embodiments.

Unless otherwise defined, all technical and scientific terms used here have the same meanings as commonly understood by those skilled in the art. The terms used in the description of the application are merely for the purpose of describing specific embodiments and are not intended to limit the implementations of the application. The term “and/or” used here indicates the inclusion of one or more and all possible combinations of related items listed.

In the description of the application, it should be understood that terms such as “central”, “upper”, “lower”, “front”, “back”, “left”, “right”, “vertical”, “horizontal”, “top”, “bottom”, “inner” and “outer” are used to indicate directional or positional relations based on the accompanying drawings merely for the purpose of facilitating and simplifying the description of the invention, do not indicate or imply that devices or elements referred to must be in a specific direction or be configured and operated in a specific direction, and thus should not be construed as limitations of the application. In the description of the application, “multiple” refers to two or more, unless otherwise stated.

In the description of the application, it should be noted that unless otherwise expressly stated and defined, terms “mount”, “link” and “connection” should be understood in a broad sense. For example, “connection” may refer to fixed connection, detachable connection or integrated connection; direct connection, indirect connection by means of an intermediate medium, or internal communication of two elements. Those skilled in the art may understand the specific meanings of these terms in the application under specific circumstances.

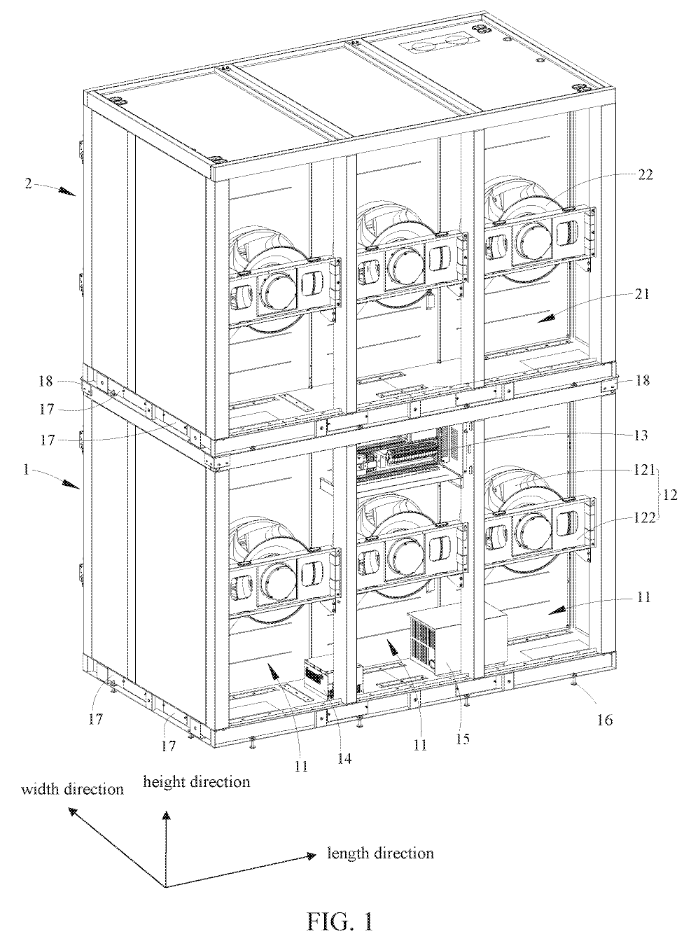

Referring to FIGS. 1-3A, an indoor unit of a fan wall type air conditioner in accordance with an embodiment of the present application, comprises a first fan wall module 1. The first fan wall module 1 includes multiple first cold air chambers 11 which are arranged side by side in a length direction of the first fan wall module 1, and a first fan assembly 12 is arranged in each of the first cold air chambers 11. An upper portion of a middle first cold air chamber 11 located in the middle is covered with a door 19 in which a display module 191 is inlaid. A low-voltage electric control box 13 and a high-voltage electric control box 110 are sequentially arranged, from outside to inside, in the first cold air chamber 11 at an inner side of the door 19, low-voltage components are arranged in the low-voltage electric control box 13, and high-voltage components are arranged in the high-voltage electric control box 110.

As shown in FIGS. 1, 2 and 8, specifically, in this embodiment, the first fan wall module 1 includes a frame and panels, and the panels cover the frame to form the chambers. Specifically, the panels cover upper and lower sides and two sides of the frame, and front and back sides of the frame are open for the arrangement of a return air valve 7 and an air outlet louver 6. The frame comprises multiple pillars which divide the first fan wall module 1 into the multiple first cold air chambers 11, and the multiple first cold air chambers 11 communicate with each other. For example, in this embodiment, the number of the first cold air chambers 11 is three. The door 19 is arranged on the upper portion of the first cold air chamber 11 in the middle, a display is arranged on the door 19, and the height of the display with respect to a floor where the indoor unit is mounted is 1.5 m, which is beneficial to operation. The door 19 may be opened for maintenance of the low-voltage electric control box 13 and the high-voltage electric control box 110 inside.

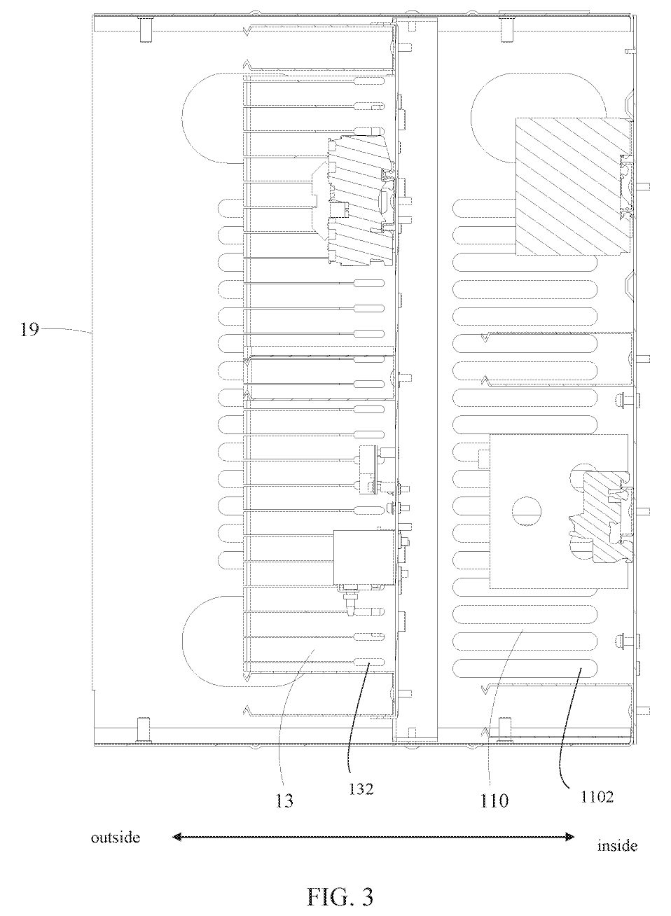

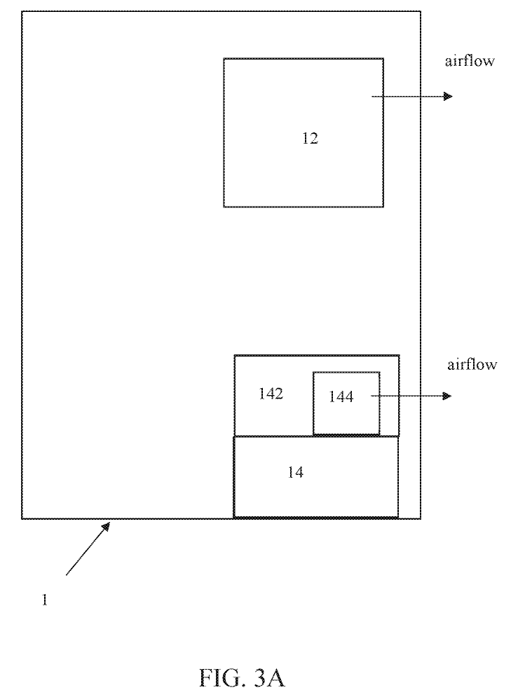

As shown in FIG. 3, the low-voltage electric control box 13 is arranged close to the door 19 and may be maintained after the door 19 is opened. The low-voltage electric control box 13 may be hinged to walls of the corresponding first cold air chamber 11. For example, in this embodiment, the low-voltage electric control box 13 is hinged to the corresponding pillars and is able to rotate with respect to the walls of the corresponding first cold air chamber 11 to expose the high-voltage electric control box 110. When the low-voltage electric control box 13 is rotated outwards with respect to the first cold air chamber 11, the high-voltage electric control box 110 is exposed to outside the first cold air chamber 11 such that the high-voltage electric control box 110 can be maintained. The low-voltage electric control box 13 and the high-voltage electric control box 110 are arranged from outside to inside, for example in a thick direction of the first fan wall module 1, in an overlapped manner to reduce the obstruction of an air outlet surface of the corresponding first cold air chamber 11 by the combination of the low-voltage electric control box 13 and the high-voltage electric control box 110, such that the overall structure is more compact. Such an arrangement increases the size in the depth direction of the module and reduces an occupied area of the front side of the indoor unit by the combination of the low-voltage electric control box 13 and the high-voltage electric control box 110.

By arranging the low-voltage electric control box 13 and the high-voltage electric control box 110 in the middle first cold air chamber 11, the low-voltage electric control box 13 and the high-voltage electric control box 110 may be cooled by the first fan 121 in the middle first cold air chamber 11. A plurality of heat-dissipation holes 132/1102 may be formed in a shell of the low-voltage electric control box 13 and a shell of the high-voltage electric control box 110 to improve the heat-dissipation effect of the low-voltage electric control box 13 and the high-voltage electric control box 110.

As shown in FIG. 1, in this embodiment, the first fan assembly 12 includes the first fan 121 and a first fan support 122, the first fan 121 is fixed to the first fan support 122, and the first fan support 122 is detachably connected to walls of the corresponding first cold air chamber 11. The first fan 121 and the first fan support 122 cooperatively form the first fan assembly 12. When the first fan assembly 12 is installed for use, the first fan 121 may be fixed to the corresponding pillars of the first fan wall module 1 by means of the first fan support 122l, and when the first fan assembly 12 need to be maintained, the first fan 121 may be disassembled from the frame by detaching the first fan support 122 from the frame, such that both assembly and disassembly of the first fan 121 are convenient, the maintenance time is shortened, and the installation efficiency is improved. In this embodiment, two opposite ends of the first fan support 122 are detachably connected to the corresponding pillars respectively.

Referring to FIG. 1 again, in this embodiment, the indoor unit of a fan wall type air conditioner further includes an active power filter (APF) 14 and a reactor 15. The APF 14 and the reactor 15 are arranged at the bottom of the first fan wall module 1 and each is located at a junction of adjacent two first cold air chambers 11. For example, in this embodiment, the APF and the reactor 15 are respectively arranged in the vicinity of two pillars on two sides of the bottom of the first cold air chamber 11 in the middle, such that the APF 14 and the reactor 15 may be cooled by the first fan 121, thus improving the reliability of the APF 14 and the reactor 15, and prolonging the service life of the APF and the reactor 15. Meanwhile, by arranging the APF and the reactor 15 at the junctions of adjacent two first cold air chambers 11, the influence of the APF and the reactor 15 on the air output may be reduced. When the APF 14 and the reactor 15 need to be maintained, the air outlet louver 6 mounted on the frame may be removed. In addition, an air outlet direction of a fan of an APF heat radiator may be consistent with that of the first fan 121 to further improve the cooling effect on the APF.

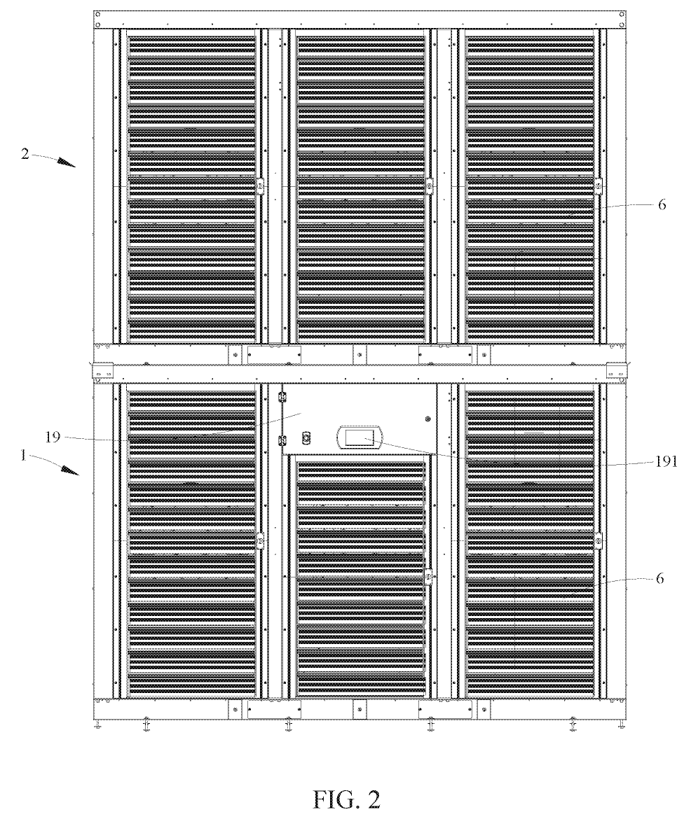

As shown in FIGS. 1 and 2, in some embodiments, the indoor unit of a fan wall type air conditioner further includes a second fan wall module 2. The second fan wall module 2 includes multiple second cold air chambers 21 which are arranged side by side. A second fan assembly 22 is arranged in each of the second cold air chambers 21. The second fan assembly 22 includes a second fan and a second fan support. The second fan wall module 2 is arranged above the first fan wall module 1 in the height direction of the indoor unit, and air inlet and outlet directions of the second fan wall module 2 are the same as those of the first fan wall module 1.

In this embodiment, the chamber structure of the second fan wall module 2 is substantially the same as that of the first fan wall module 1, that is, the second fan wall module 2 comprises three second cold air chambers 21, and the second cold air chambers 21 correspond to the first cold air chambers 11 in a one-to-one correspondence. The second fan assembly 22 is completely the same as the first fan assembly 12 in structure and is connected to the corresponding second air cold chamber 21 in the same way as the first fan assembly 12, which will not be detailed here.

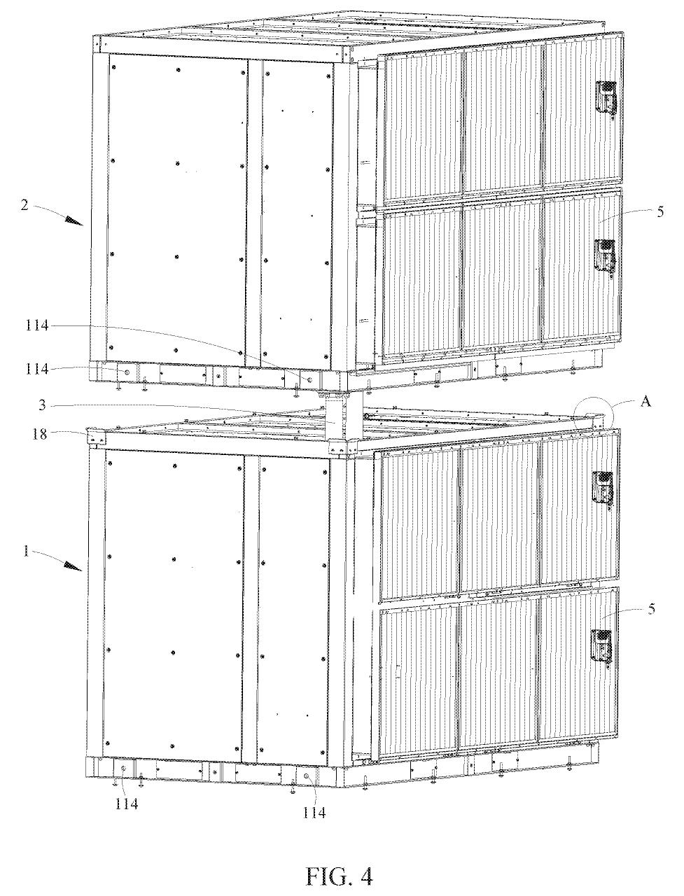

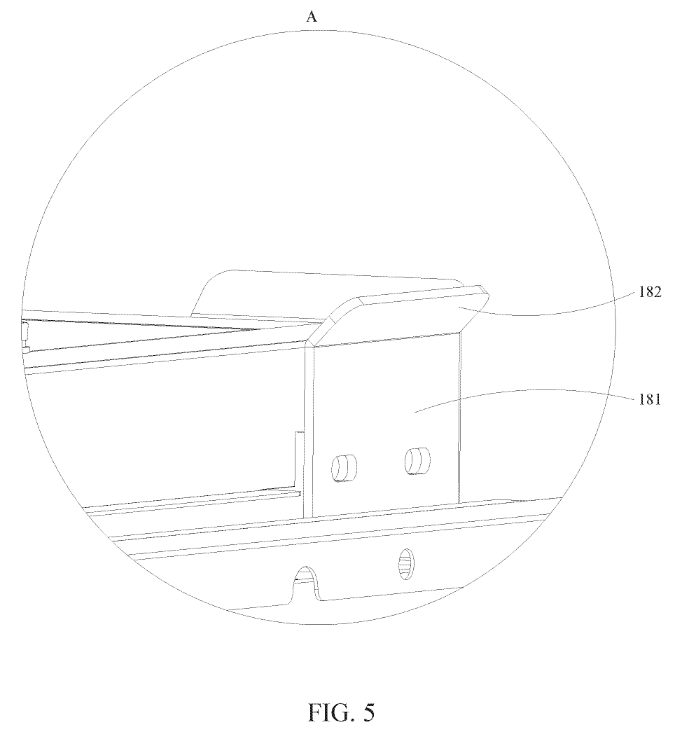

As shown in FIGS. 1 and 4, to facilitate installation and positioning of the second fan wall module 2 and the first fan wall module 1, a position limiter 18 is arranged at each of four corners of the top of the first fan wall module 1. As shown in FIG. 5, the position limiter 18 includes a fixing portion 181 and a positioning portion 182. The fixing portion 181 is fixedly connected to an outer wall of the first fan wall module 1, for example, the fixing portion 181 may be fixedly connected to two adjacent outer walls of the first fan wall module 1 by means of bolts. The positioning portion 182 is arranged at the top of the fixing portion 181. The positioning portion 182 is bent inclinedly and outwards from the fixing portion 181 and configured to form a guide and limit structure to facilitate installation and positioning of the second fan wall module 2 on the first fan wall module 1. By bending the positioning portion 182 outwards along two adjacent outer walls of the first fan wall module 1, the second fan wall module 2 may quickly slide to the top of the first fan wall module 1 along slopes formed by the bent positioning portion 182 and may be quickly and accurately positioned to facilitate installation, thus improving installation efficiency. The second fan wall module 2 and the first fan wall module 1, after being positioned, may be connected and fixed by means of connecting members such as bolts.

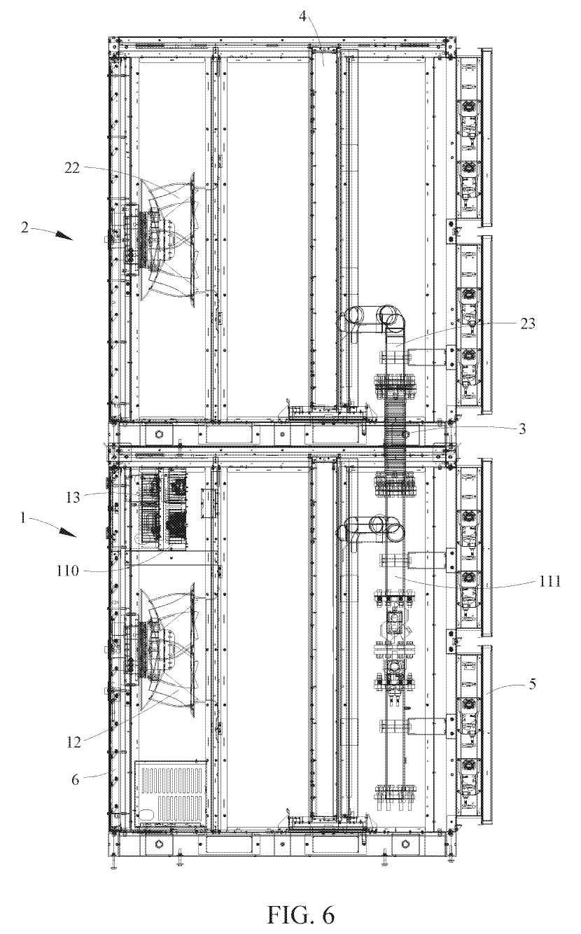

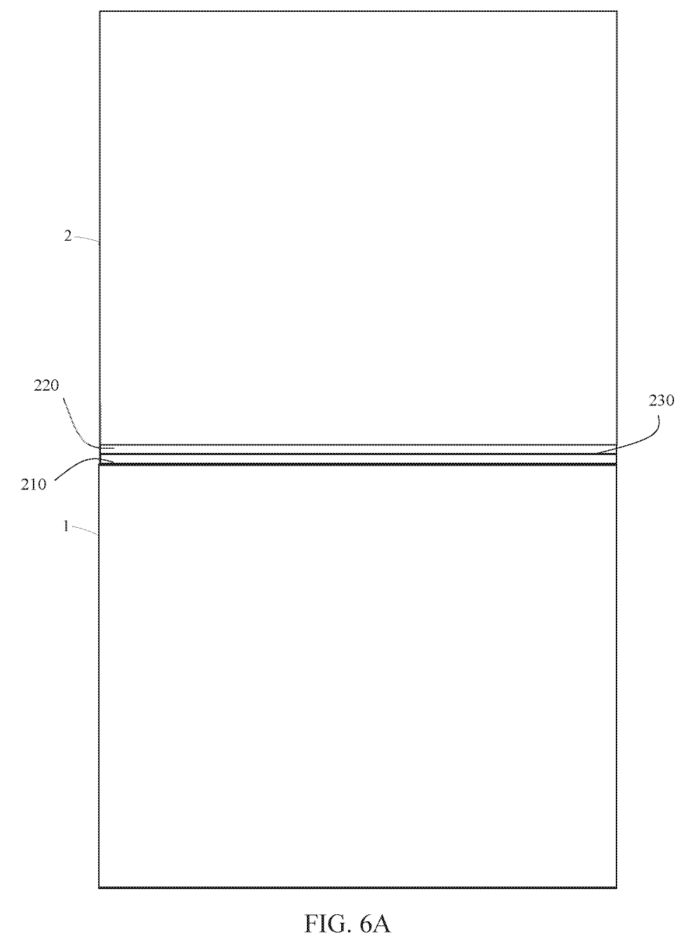

As shown in FIGS. 6 and 6A, to facilitate pipe connection between the first fan wall module 1 and the second fan wall module 2, a detachable first maintenance plate 210 may be arranged at the top of the first fan wall module 1, and a first pipe assembly 111 is arranged in the chambers below the first maintenance plate 210.

A detachable second maintenance plate 220 is arranged at the bottom of the second fan wall module 2, the second maintenance plate 220 corresponds to the first maintenance plate 210, and a second pipe assembly 23 is arranged in the chambers above the second maintenance plate 220.

The indoor unit of a fan wall type air conditioner further includes a connecting hose assembly 3. The connecting hose assembly 3 includes a corrugated hose and two loose flanges disposed around the corrugated hose, and the two loose flanges are respectively connected to the first pipe assembly 111 and the second pipe assembly 23.

The first pipe assembly 111 and the second pipe assembly 23 correspond to each other vertically. Through-holes corresponding to the pipe assemblies (the first pipe assembly 111 or the second pipe assembly 23), are formed in the panels of the first fan wall module 1 and the second fan wall module 2 respectively to allow the corresponding pipe assemblies to penetrate therethrough. The first maintenance plate 210 and the second maintenance plate 220 respectively cover the corresponding through-holes. By detaching the first maintenance plate 210 and the second maintenance plate 220, the operation space may be enlarged to facilitate maintenance and installation of the pipe assemblies, and the requirement for fastening the flanges is satisfied. Welded flanges are arranged at ends of the first pipe assembly 111 and the second pipe assembly 23 respectively, the two loose flanges of the connecting hose assembly 3 are threadedly connected to the two welded flanges respectively, and the corrugated hose can solve the problem of inconvenience of assembly caused by machining errors of the pipe assemblies.

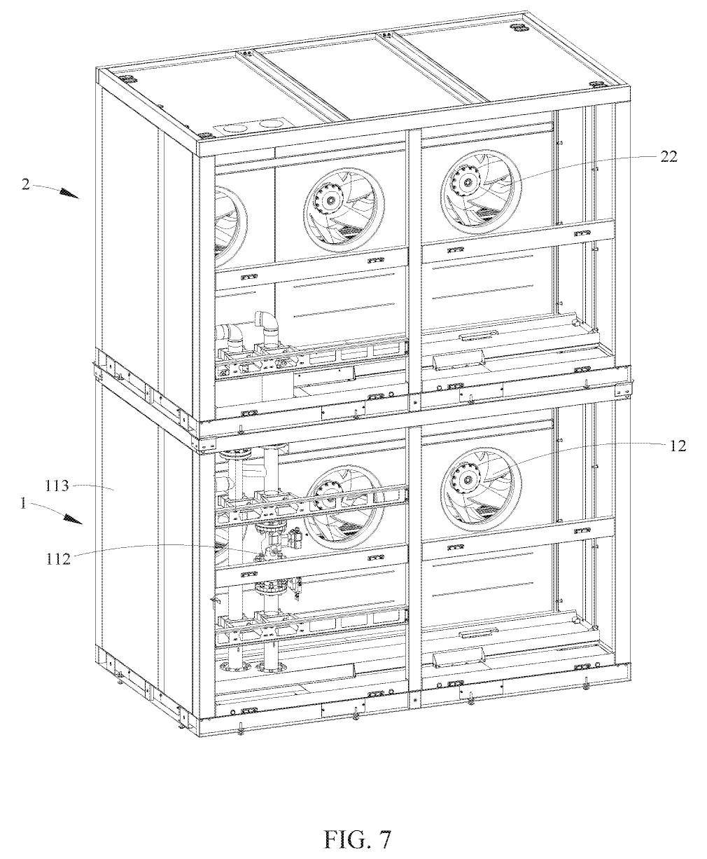

As shown in FIG. 7, in this embodiment, the indoor unit of a fan wall type air conditioner further includes a valve assembly 112. The valve assembly 112 is arranged in the first fan wall module 1 and is close two side plates 113 on two sides of the first fan wall module 1, and the side plates 113 are detachably connected to the frame of the corresponding first cold air chambers 11. The valve assembly 112 is arranged in the first fan wall module 1 and may be maintained by detaching the side plate 113 (named as panel) on one side of the first fan wall module 1.

To prevent the air output of the indoor unit of a fan wall type air conditioner from being affected by sealing problems, a sealing member 230 may be arranged between the first fan wall module 1 and the second fan wall module 2 to improve the sealing effect of a joint between the first fan wall module 1 and the second fan wall module 2 and seal a seam caused by machining or assembly to avoid air leakage, which may otherwise compromise the performance of the indoor unit. For example, thermal insulation cotton may be wrapped with a polytetrafluoroethylene adhesive to form the sealing member 230 for sealing the joint between the first fan wall module 1 and the second fan wall module 2. The sealing member 230 not only improves the sealing effect, but also improves the installation stability of equipment. By wrapping the thermal insulation cotton with the polytetrafluoroethylene adhesive, the frictional force applied to the thermal insulation cotton in the installation process may be reduced, thus reducing abrasion of the thermal insulation cotton.

To improve the corrosion resistance of the indoor unit of a fan wall type air conditioner to satisfy installation requirements in different environments, the frames and panels of the first fan wall module 1 and the second fan wall module 2 may be made from galvanized plates coated with a protective material. Fasteners between the panels and the frames may be made from stainless steel, such that the overall corrosion resistance of the indoor unit is improved to make the indoor unit suitable for some special environments.

As shown in FIGS. 1 and 4, to facilitate lifting and transportation of the indoor unit of a fan wall type air conditioner, lifting holes 114 and forklift holes 17 may be formed in the bottoms of the two fan wall modules (the first fan wall module 1 and the second fan wall module 2). For example, the forklift holes 17 may be elongated and formed in the front surfaces (the air flowing out from the front surface) and side surfaces (adjacent to the front surfaces) of the bottoms of the fan wall modules, and the lifting holes 114 are formed in the side surfaces of the bottoms of the fan wall modules. The forklift holes 17 and the lifting holes 114 are not covered by the panels of the first fan wall module 1.

As shown in FIG. 1, levelling foundation bolts 16 may be arranged at the bottom of the first fan wall module 1, such that the first fan wall module 1 may be installed as level as possible.

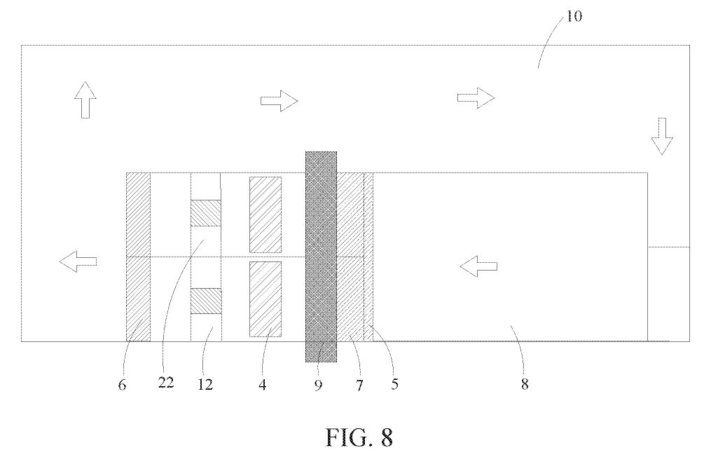

As shown in FIGS. 6 and 8, the two fan wall modules each further include a filter screen 5, a return air valve 7, a heat exchanger 4 and an air outlet louver 6. The filter screen 5 is arranged on an outer side of the return air valve 7 and directly connected to a sealed heat passage 8 of an indoor return air vent. For example, in a case where a fan wall type air conditioner is applied to a data centre, mounting holes may be formed in a wall of a room where the data centre is located, the return air valves 7 and the filter screens 5 are arranged on an inner side of the wall 9, that is, the return air valves 7 and the filter screens 5 are located in the same room as heat generation equipment of the data centre. The heat changers 4, and the fan assemblies and the air outlet louvers 6 are arranged in an equipment room on an outer side of the wall 9, such that the data centre is tidier, and the indoor unit for the fan wall type air conditioner may be maintained in the equipment room and will not be mistouched by irrelevant personnel. The heat exchangers 4, fan assemblies and the air outlet louvers 6 are sequentially arranged outwards from the wall 9. Indoor hot air is filtered by the filter screens 5, then enters the cold air chambers (the first cold air chambers 11 and the second cold air chambers 21) after passing through the return air valves 7 and exchanges heat with the heat exchangers 4 to be cooled. The cooled air is blown out of the cold air chambers via the air outlet louvers 6 by the fans, and air outlets of the air outlet louvers 6 are in communication with an indoor air outlet passage 10 via pipes, such that the cold air can be blown into the indoor environment to decrease the indoor temperature.

An embodiment of the application further provides a fan wall type air conditioner, including an outdoor unit and the indoor unit of a fan wall type air conditioner disclosed above. The outdoor unit and the indoor unit of a fan wall type air conditioner are connected electrically and are in fluid communication with each other by means of a pipeline to form a refrigerant circulation system. Specifically, the fan wall type air conditioner further includes a compressor, an outdoor heat exchanger 4 and an expansion valve. The compressor, the heat exchanger 4 (the indoor unit of a fan wall type air conditioner), the expansion valve and the outdoor heat exchanger 4 are in fluid communication with each other by means of the pipeline to form the refrigerant circulation system, and the temperature of an indoor environment is controlled by compressing a refringent by the compressor.

According to the indoor unit of a fan wall type air conditioner and the fan wall type air conditioner provided by the embodiments of the application, the indoor unit of a fan wall type air conditioner is divided into two or more modules which can be disassembled during transportation, such that the size during transportation is decreased, and transportation of the indoor unit of a fan wall type air conditioner is convenient. Components in the first fan wall module and components the second fan wall type air conditioner are designed separately and circuits of the two modules are connected side by side, such that when one fan wall module breaks down, other fan wall modules may be used normally. The upper and lower fan wall modules are in fluid communication with each other by means of a pipeline assembly, such that installation is facilitated, and inconvenience of installation caused by assembly errors of the pipe assemblies is avoided. The corrugated hose and the pipe assembly are integrated, and multi-angle installation may be realized by adjusting the loose flanges, thus improving the convenience of construction. According to the embodiments of the application, the layout of internal components is improved; the electric control boxes (the high-voltage electric control box and the low-voltage electric control box) are arranged right in the front of the unit, such that the layout is compact; and the overlapped arrangement of the electric control boxes reduces the obstruction of the air outlet area of the front side of the indoor unit by the electric control boxes and facilitates operation of the display and maintenance of the high-voltage and low-voltage components. The layout of the APF and the reactor guarantees the heat-dissipation effect of the APF and the reactor, facilitates maintenance of the APF and the reactor and minimize the obstruction of the air outlet area. The modular design of the fan assemblies facilitates assembly, disassembly and maintenance. During installation, the upper and lower fan wall modules may be lifted and transported by means of tools cooperating with the lifting holes and the forklift holes and may be quickly aligned with each other by means of the position limiters, thus reducing installation errors and improving installation efficiency.

It should be noted that terms such as “comprise” and “include” and any other variants used here are intended to indicate non-exclusive inclusion, such that a process, method, article or device including a series of elements not only includes the elements that are clearly listed, but also includes other elements that are not clearly listed, or includes inherent elements of the process, method, article or device. Unless otherwise additionally stated, an element defined by “include a/an” shall not exclude the presence of other identical elements in a process, method, article or device including said element.

The above embodiments are merely specific ones of the application, and the protection scope of the application is not limited to the above embodiments. All transformations or substitutions easily obtained by any skilled in the art within the technical scope disclosed by the application should fall within the protection scope of the application. Therefore, the protection scope of the application should be defined by the claims.

What is claimed is:

1. An indoor unit of a fan wall type air conditioner, comprising a first fan wall module, wherein the first fan wall module comprises multiple first cold air chambers which are arranged side by side, and a first fan assembly is arranged in each of the first cold air chambers;
an upper portion of a middle one of the first cold air chambers is covered with a door, and a display module is inlaid in the door;
a low-voltage electric control box and a high-voltage electric control box are sequentially arranged, from outside to inside, in the upper portion of the middle one of the first cold air chambers located at an inner side of the door; and
low-voltage components are arranged in the low-voltage electric control box, and high-voltage components are arranged in the high-voltage electric control box.

2. The indoor unit of a fan wall type air conditioner according to claim 1, wherein the low-voltage electric control box is hinged to a wall of the middle one of the first cold air chambers and is able to rotate with respect to the wall of the middle one of the first cold air chambers to expose the high-voltage electric control box.

3. The indoor unit of a fan wall type air conditioner according to claim 2, wherein a plurality of heat-dissipation holes is formed in a shell of the low-voltage electric control box and/or the high-voltage electric control box.

4. The indoor unit of a fan wall type air conditioner according to claim 1, wherein the first fan assembly comprises a first fan and a first fan support, the first fan is fixed to the first fan support, and the first fan support is fixedly connected to a wall of a corresponding one of the first cold air chambers in which the first fan assembly is received.

5. The indoor unit of a fan wall type air conditioner according to claim 4, wherein the first fan support is detachably connected to the wall of the corresponding first cold air chamber, and the first fan is located at an inside of the first fan support.

6. The indoor unit of a fan wall type air conditioner according to claim 1, wherein an active power filter (APF) and a reactor are arranged in the first fan wall module.

7. The indoor unit of a fan wall type air conditioner according to claim 6, wherein the APF and the reactor are arranged at a bottom of the first fan wall module, and each of the APF and the reactor is located at a junction of adjacent two said first cold air chambers; or
the low-voltage electric control box and the high-voltage electric control box are overlapped in a width direction of the first fan wall module, the first fan assembly in the middle one of the first cold air chambers is located under the low-voltage electric control box and the high-voltage electric control box, and the reactor is located under the first fan assembly in the middle one of the first cold air chambers.

8. The indoor unit of a fan wall type air conditioner according to claim 6, wherein an APF radiator is arranged on the APF, and an air outlet direction of a fan of the APF radiator is consistent with that of the first fan assembly.

9. The indoor unit of a fan wall type air conditioner according to claim 1, further comprising a second fan wall module, wherein the second fan wall module comprises multiple second cold air chambers which are arranged side by side, and a second fan assembly is arranged in each of the second cold air chambers; and
the second fan wall module is arranged above the first fan wall module, and air inlet and out directions of the second fan wall module are consistent with those of the first fan wall module respectively.

10. The indoor unit of a fan wall type air conditioner according to claim 9, wherein position limiters are arranged at four corners of a top of the first fan wall module respectively, each of the position limiters comprises a fixing portion and a positioning portion, the fixing portion is fixedly connected to outer walls of the first fan wall module, and the positioning portion is arranged at a top of the fixing portion and bent outwards and inclinedly from the fixing portion to form a guide and limit structure which is configured to facilitate installation and positioning of the second fan wall module on the first fan wall module.

11. The indoor unit of a fan wall type air conditioner according to claim 9, wherein a detachable first maintenance plate is arranged at a top of the first fan wall module, and a first pipe assembly is arranged in the chambers below the first maintenance plate;
a detachable second maintenance plate is arranged at a bottom of the second fan wall module and corresponds to the first maintenance plate, and a second pipe assembly is arranged in the chambers above the second maintenance plate; and
the first maintenance plate and the second maintenance plate are configured to enlarge an operation space.

12. The indoor unit of a fan wall type air conditioner according to claim 11, further comprising a connecting hose assembly, wherein the connecting hose assembly comprises a corrugated hose and two loose flanges disposed around the corrugated hose, and the two loose flanges are respectively connected to the first pipe assembly and the second pipe assembly.

13. The indoor unit of a fan wall type air conditioner according to claim 9, wherein the indoor unit further comprises a valve assembly, wherein the valve assembly is arranged in the first fan wall module and is close to side plates on two sides of the first fan wall module, and the side plates are detachably connected to walls of the corresponding first cold air chambers.

14. The indoor unit of a fan wall type air conditioner according to claim 9, wherein the indoor unit further comprises a sealing member, wherein the sealing member is arranged between the first fan wall module and the second fan wall module to isolate the first cold air chambers in the first fan wall module from the second cold air chambers in the second fan wall module.

15. The indoor unit of a fan wall type air conditioner according to claim 9, wherein frames and panels of the first fan wall module and the second fan wall module are made from galvanized plates coated with a protective material, and fasteners between the panels and the frames are made from stainless steel.

16. The indoor unit of a fan wall type air conditioner according to claim 9, wherein lifting holes and forklift holes are formed in a bottom of the first fan wall module and a bottom of the second fan wall module respectively.

17. The indoor unit of a fan wall type air conditioner according to claim 1, wherein levelling foundation bolts are arranged at a bottom of the first fan wall module.

18. The indoor unit of a fan wall type air conditioner according to claim 9, wherein the first fan wall module and the second fan wall module each further comprise a filter screen, a return air valve, a heat exchanger and an air outlet louver which are sequentially arranged from an air inlet side thereof to an air outlet side in a width direction thereof.

19. The indoor unit of a fan wall type air conditioner according to claim 1, wherein lifting holes are formed in a front surface of a bottom of the first fan wall module; and
elongated forklift holes are formed in a front surface and a side surface of the bottom of the first fan wall module.

20. A fan wall type air conditioner, comprising an outdoor unit and the indoor unit of the fan wall type air conditioner according to claim 1, wherein the outdoor unit and the indoor unit are connected electrically and in fluid communication with each other by means of a pipeline to form a refrigerant circulation system.
